(19) United States
(12) Patent Application Publication
(10) Pub. No.: US 2016/0300798 A1
(43) Pub. Date: Oct. 13, 2016

(54) DIRECTIONAL COUPLER

(71) Applicant: Avago Technologies General IP (Singapore) Pte. Ltd., Singapore (SG)

(72) Inventors: William Tang, Austin, TX (US); Eric Kimball, Austin, TX (US); Jim McElwee, Austin, TX (US)

(21) Appl. No.: 14/683,930

(22) Filed: Apr. 10, 2015

(51) Int. Cl. H01L 23/552; H01L 23/528; H01L 23/522

(52) U.S. Cl. CPC H01L 23/552; H01L 23/5227; H01L 23/528

(57) ABSTRACT

Directional couplers are used to detect forward power delivered by a power amplifier. Mechanisms are provided herein which improve the accuracy of the power detection in the presence of external noise. Accuracy in power detection can be used to simplify the design of the power control loop.

### FIELD OF THE DISCLOSURE

The present disclosure is generally directed toward couplers and, in particular, to directional couplers used to detect forward power delivered by devices.

### BACKGROUND

In electronics, directional couplers are passive devices used to couple power traveling between the devices. A specific proportion of the power traveling in one transmission line can be coupled to output through another connection or port. Directional couplers can often be used to couple a defined amount of the electromagnetic power in a transmission line to a port enabling the signal to be used for another circuit. For example, a directional coupler can be used to detect forward power delivered by a power amplifier.

A typical directional coupler can include a pair of coupled transmission lines or coils. The coils can lie in close proximity and can be used to determine the amount of current induced by a monitored circuit. However, often times, external components and devices also generate magnetic fields that can interfere with the current induced by the monitored device, leading to an incorrect power measurement.

### BRIEF DESCRIPTION OF THE DRAWINGS

The present disclosure is described in conjunction with the appended figures, which are not necessarily drawn to scale:

FIG. 1 is a block diagram depicting a general communication architecture in accordance with at least some embodiments of the present disclosure;

FIG. 2 depicts a figure eight directional coupler in accordance with at least some embodiments of the present disclosure;

FIG. 3 depicts a metal layout for a figure eight coupler in accordance with at least some embodiments of the present disclosure;

FIG. 4 depicts a first branch coil on a coupler in accordance with at least some embodiments of the present disclosure;

FIG. 5 depicts a second branch coil on a coupler in accordance with at least some embodiments of the present disclosure;

FIG. 6A depicts a first coupler configuration in accordance with at least some embodiments of the present disclosure;

FIG. 6B depicts a second coupler configuration in accordance with at least some embodiments of the present disclosure;

FIG. 6C depicts a third coupler configuration in accordance with at least some embodiments of the present disclosure;

FIG. 6D depicts a fourth coupler configuration in accordance with at least some embodiments of the present disclosure;

FIG. 6E depicts a fifth coupler configuration in accordance with at least some embodiments of the present disclosure;

FIG. 6F depicts a sixth coupler configuration in accordance with at least some embodiments of the present disclosure;

FIG. 6G depicts a seventh coupler configuration in accordance with at least some embodiments of the present disclosure;

FIG. 7 depicts an integrated circuit with a figure eight coupler in the presence of external noise in accordance with at least some embodiments of the present disclosure; and

FIG. 8 is a flow chart illustrating a method of operating a coupler to achieve external noise rejection in accordance with at least some embodiments of the present disclosure.

### DETAILED DESCRIPTION

The ensuing description provides embodiments only, and it is not intended to limit the scope, applicability, or configuration of the claims. Rather, the ensuing description will provide those skilled in the art with an enabling description for implementing the embodiments. It being understood that various changes may be made in the function and arrangement of elements without departing from the spirit and scope of the appended claims.

While embodiments of the present disclosure will be primarily described in connection with a directional coupler for external magnetic field rejection, it should be appreciated that embodiments of the present disclosure are not so limited.

Various aspects of the present disclosure will be described herein with reference to drawings that are schematic illustrations of idealized configurations. It should be appreciated that while particular coupler arrangements and configurations are described herein, embodiments of the present disclosure are not limited to the illustrative display configurations and/or coupler depictions and descriptions. Specifically, it should be appreciated that features, functions and various views may be replaced or added to achieve a similar function without departing from the scope of the present disclosure.

Presented herein are embodiments of a system and method that solve the drawbacks associated with electromagnetic interference on integrated circuit chips. The embodiments may relate to a directional coupler. The directional coupler can include two or more main branch coils and coupled branch coils that are arranged in a figure eight configuration. The overall design and functionality of the system described herein is, as one example, to provide a more accurate means for power detection by the directional coupler.

It is one object of the present disclosure to provide an improved directional coupler that overcomes and addresses the above mentioned drawbacks of traditional couplers. In particular, embodiments of the present disclosure provide a directional coupler with two branch coils which lie in close proximity with one another and work jointly to reject external electromagnetic interferences generated by nearby components.

Embodiments of the present disclosure also enable power detection accuracy in the presence of external noise. Such power detection accuracy can simplify the design of the power control loop at the system-level. For example, system level design can be improved on a cell phone, where the transceives chip can use information from the directional coupler to control the amount of power transmitted at the antenna.

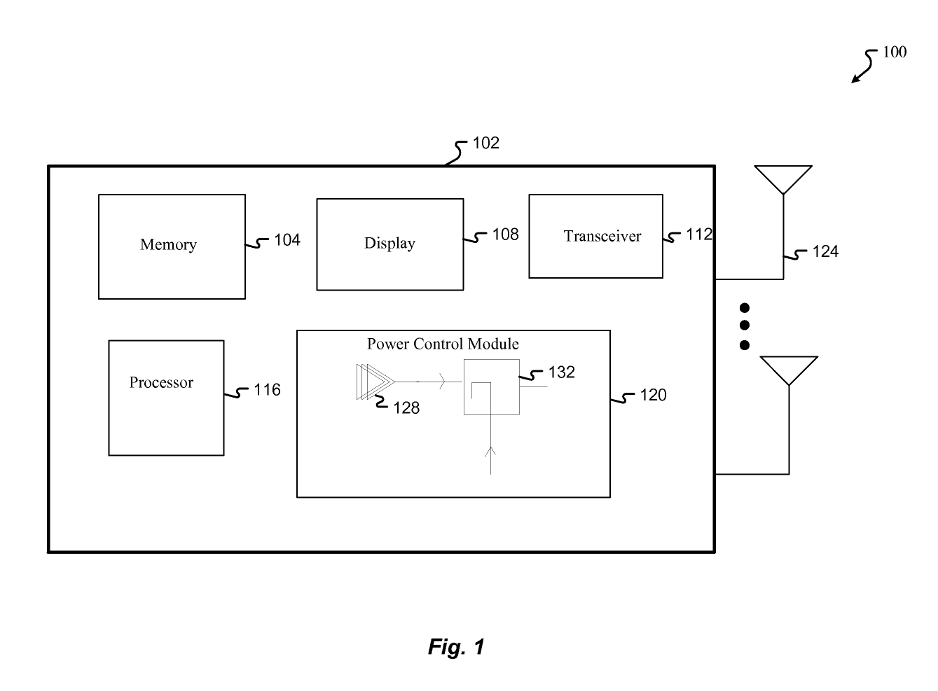

Communication devices are one example a system of various modules and components that work together to provide information to a user. FIG. 1 illustrates a general communication device architecture 100 with some of the general modules that can be found in such system. Although a communication device 102 will be described as including a power control module 120 in accordance with embodiments of the present disclosure, it should be appreciated that other electronic devices (e.g., devices other than a communication device) can include and benefit from utilization of a power control module 120. The discussion of the communication device 120 herein is intended to be for illustrative purposes only and should not be construed as limiting embodiments of the present disclosure in any way.

The communication device 102 can be, but is not limited to, handsets, mobile devices, Personal Digital Assistants (PADS), smart phones, tablets, notebooks, laptop, desk tops, etc. The communication device 102 can include a processor 116, which can be used for processing the data within the architecture of the communication device 102. In particular, the processor 116 may be configured to execute computer-readable instructions stored in memory 104, process user inputs received at a user input of the communication device 102, process user outputs to be displayed via a display 108 of the communication device 102, process data transmitted by and received at the transceives 112, and the like. The processor 116 can alternatively or additionally include Application Specific Integrated Circuits (BASICS), digital signal processors, programmable logic, controllers, logic circuits, gate arrays, specific purpose computers, and the like. The processor 116 can communicate, retrieve and store instructions on a memory 104. The memory 104 can include long term and short term memory as well as RAM, DRAM, SDRAM, and other storage devices, non-volatile memory, and media.

The communication device architecture can also include a display 108. The processor 116 can communicate with the display 108. The display can be an LAD display for example. In some embodiments, the display 108 may correspond to a touch-sensitive display (e.g., a combination user input and user output device).

The processor can further communicate with a transceives 112. The transceives 112 can be a receiver and/or transmitter for receiving and transmitting signals over one or more antennae 124. The antennas can further be coupled to a power control module 120. The power control module 120 can include at least a power amplifier 128 and a coupler 132. The power amplifier 128 is often used to drive the antennas by providing/converting a low-power signal to a signal with more significant power. The power amplifier 128 may be used to drive other modules of the communication device 102 as well. A coupler 132 is often used and coupled to the power amplifier 128. The coupler 132 can be used to detect the forward power delivered by the power amplifier to the antennas 124 or other components of the communication device 102. Detection of the power delivered by the power amplifier 128 can help the transceives 112 control the amount of power to be transmitted by the one or more antennae 124.

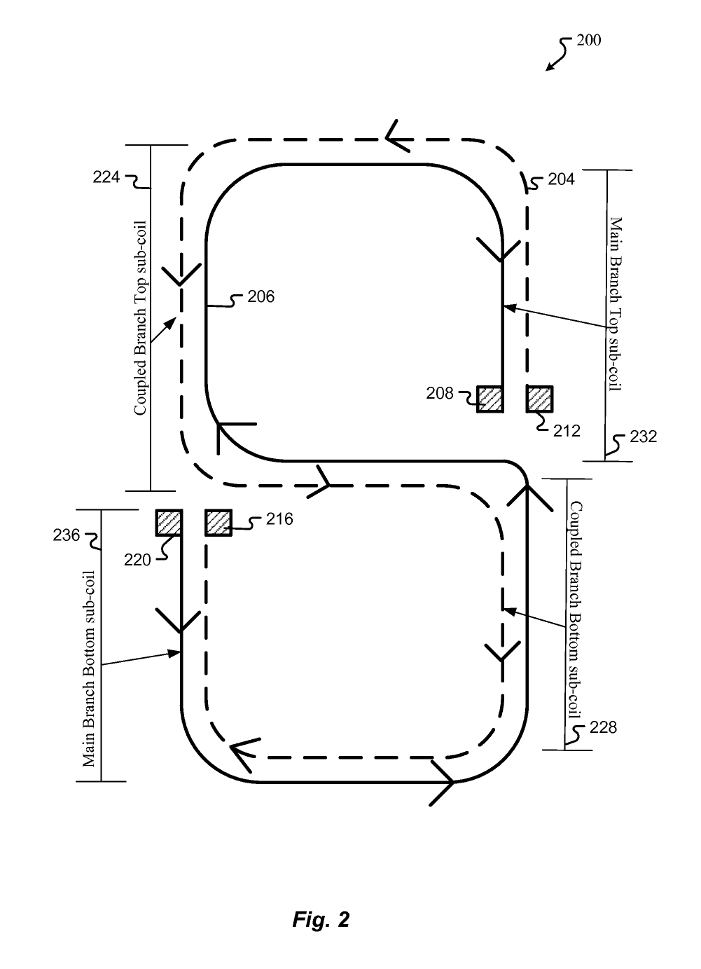

The modules depicted and described in FIG. 1 and others known in the art can be used with the communication device 102 and can be configured to perform the operations described herein and in conjunction with FIGS. 2-8.

To improve the accuracy of the power detected by the coupler 132, a figure eight directional coupler 200 is introduced in FIG. 2. The figure eight directional coupler 200 may correspond to a specific type of coupler 132, but should not be interpreted as limiting the coupler 132 to a specific coupler configuration.

A general directional coupler 132 generally includes two branches/coils. These branches are often termed a main and a coupled branch. The figure eight directional coupler 200 in FIG. 2 is shown to include these two branches, the main branch 206 and the coupled branch 204. The main branch 204 is the branch on which the main power received directly from the power amplifier 128 is flowing. A magnetic field will often form around the main branch 206 due to the fact that current is flowing in the path. The coupled branch 204 is a branch located in close proximity to the main branch 206 and is used to detect the magnetic field produced in the main branch 204. The main branch 204 can include an input to the main branch 220 and an output to the main branch 208. Similarly, the coupled branch 204 can also include an input/output (i.e., input to the coupled branch 216 and output of the coupled branch 212). The figure eight directional coupler 200 can alternatively have more or less branches for magnetic field detection.

In many instances, the power detected by the coupled branch 204 can be imprecise. This is largely due to the magnetic fields generated by nearby components, and signals flowing within a proximity to the directional coupler. Such magnetic fields can derive from external components which can include at least inductors and transformers, as well as high frequency signals routed nearby. As a result, the coupled branch 204 will detect the magnetic fields (i.e., magnetic noise) generated by the external components leading to an incorrect power detection.

To improve the accuracy of power detection by the coupled branch 204, external magnetic noise should be rejected. Figure eight directional coupler 200 introduces a coupled branch with a figure eight configuration, where the coupled branch 204 is split into two sub-coils. The two sub-coils can include at least a coupled branch top sub-coil 224 and a coupled branch bottom sub-coil 228. The two sub-coils can be wound in opposite polarity and connected in series. Because the two sub-coils are placed physically close together, external magnetic noise incident on these two sub-coils can be in the same direction. Also, because the two sub-coils are wound in opposite directions, the electromagnetic force induced by this external magnetic noise will have opposite polarities from one another (e.g., one going into the page and one coming out of the page). Furthermore, since these two sub-coils (i.e., coupled branch top sub-coil 224 and coupled branch bottom sub-coil 228) are connected in series, the opposite electromagnetic force from each coil will substantially cancel each other. Thus, the net electromagnetic force across the entire coupled branch induced by the external magnetic noise is zero, which directly translates to zero response by the directional coupler to such external magnetic field.

To overcome the possibility of rejecting the magnetic field of the main branch 206, the main branch 206 can also split be into two sub-coils (i.e., main branch top sub-coil 232 and main branch bottom sub-coil 236). The two main branch sub-coils 232, 236, will also generate electromagnetic force. However, appropriate placement of the two main branch sub-coils 232, 236 with respect to the two coupled branch sub-coils 224, 228 will induce an electromagnetic force of same polarity as the two coupled branch sub-coils 224, 228. Therefore, the wounding of all four sub-coils (main branch sub-coils 232, 236 and coupled branch sub-coils 224, 228) will allow the figure eight directional coupler 200 to reject external magnetic noise and only respond and detect the current flowing in the main branch 206. As an example, the main branch 206 can be placed underneath the coupled branch 204. As another example, the main branch top sub-coil 232 is placed underneath the coupled branch top sub-coil 224 and the main branch bottom sub-coil 236 is placed on top of the coupled branch bottom sub-coil 228. In yet another example, the main branch top sub-coil 232 is placed on top of the coupled branch top sub-coil 224 and the main branch bottom sub-coil 236 is placed underneath of the coupled branch bottom sub-coil 228. Still yet in another example, the main branch 206 is placed on top of the coupled branch 204. Alternatively, many branches are layered and configured in various arrangements.

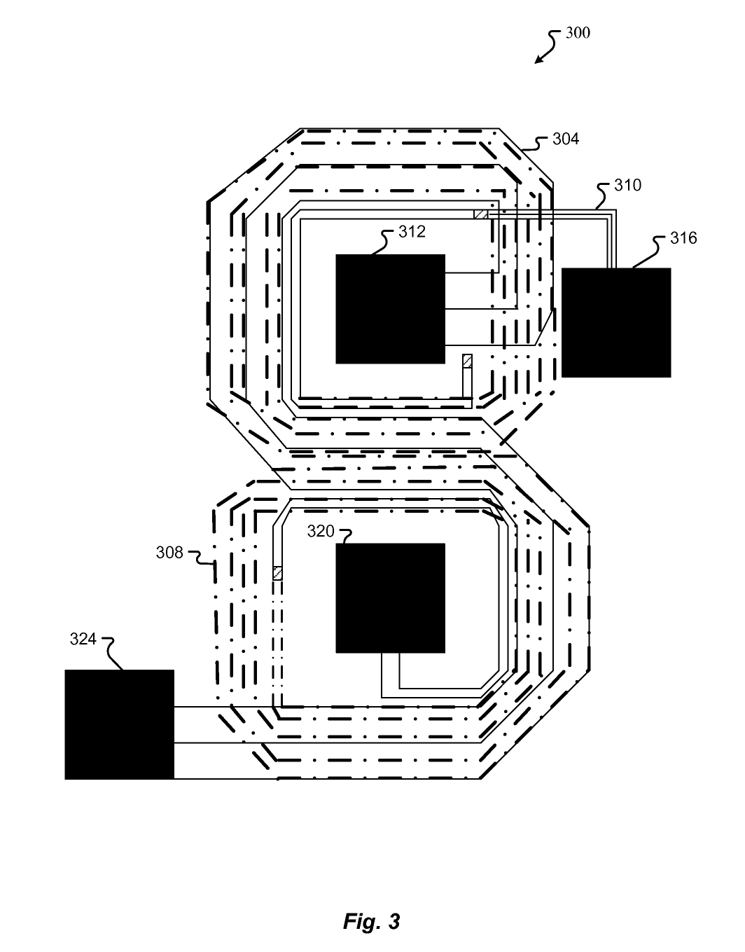

FIG. 3 illustrates a metal layer layout 300 for the figure eight directional coupler where the main branch 206 (and corresponding sub-coils 232, 236) is placed underneath the coupled branch 204 (and corresponding sub-coils 224, 228). As known by those skilled in the art, integrated circuit (IC) chips are a set of components and electronics placed on a chip of semiconductor material. Integrated circuit chips are generally fabricated in a layered process. Many layers overlap which are created through an imaging, deposition and etching process. The layers can be for example, but not limited to diffusion layers, implant layers, metal layers, contact layers, etc. In general, transistors and even couplers are formed on the metal layers. FIG. 3 illustrates at least some of the metal layers involved in the formation of the figure eight directional coupler. Metal 8 308 is a top layer that can be used to form the main branch coil, while Metal 6 304 is a bottom layer that can be used to form the coupled branch coil. A Metal 7 310 is a middle layer that can be used for interconnection between at least Metal 6 304 and external connections and/or bond pad 316. The metal layers can be copper, aluminum or other like metals. Other bond pads 312, 320, 324 are also available for connection. Vias in a component or within the integrated circuit chip can be used to provide a connection between layers and sides of the IC chip. The vias have a via capture side or bond pad (i.e., bond pads 312, 316, 320, 324) which can be used provide contact between components and/or sides of the integrated circuit chip.

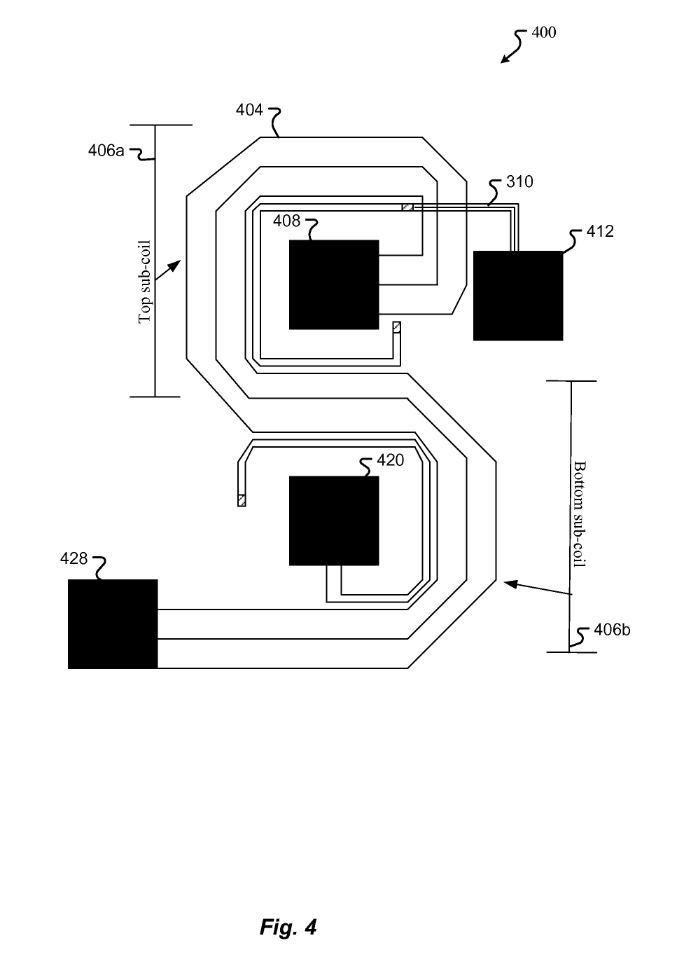

FIG. 4 depicts a first branch coil 400 of a directional coupler. The first branch coil 400 can be the coupled branch coil 404 on the directional figure eight coupler. The figure eight directional coupler as previously described can include a coupled branch coil 404 which includes a top sub-coil 406a and a bottom sub-coil 406b in series. The coupled branch coil can be a Metal 6 304 bottom copper layer as described above and in conjunction with FIG. 3. Metal 7 310 is present to illustrate the interconnection between the coupled branch coil 404 and other metal layers, components, and to bond pad 412. Other bond pads 408, 420, 428 are also present that can be used for the interconnection between the coupled branch coil 404 and the other components, metal layers, etc.

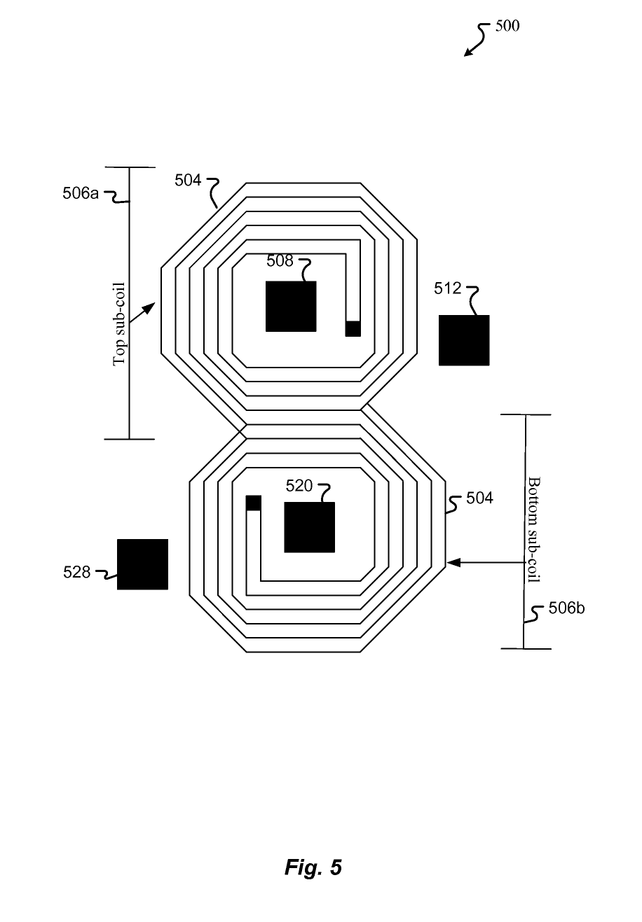

FIG. 5 depicts a second branch coil 500 of a directional coupler. The second branch coil 500 can be the main branch coil 504 of the directional figure eight coupler. The figure eight coupler directional coupler as previously described and in conjunction with FIG. 2 can include a main coupled branch within includes a top sub-coil 506a and a bottom sub-coil 506b connected in series. The main branch coil 504 can be a Metal 8 308 top aluminum layer. Bond pads 508, 512, 520, 528 are again present for interconnection between metal layers, IC chip sides, and/or other external components.

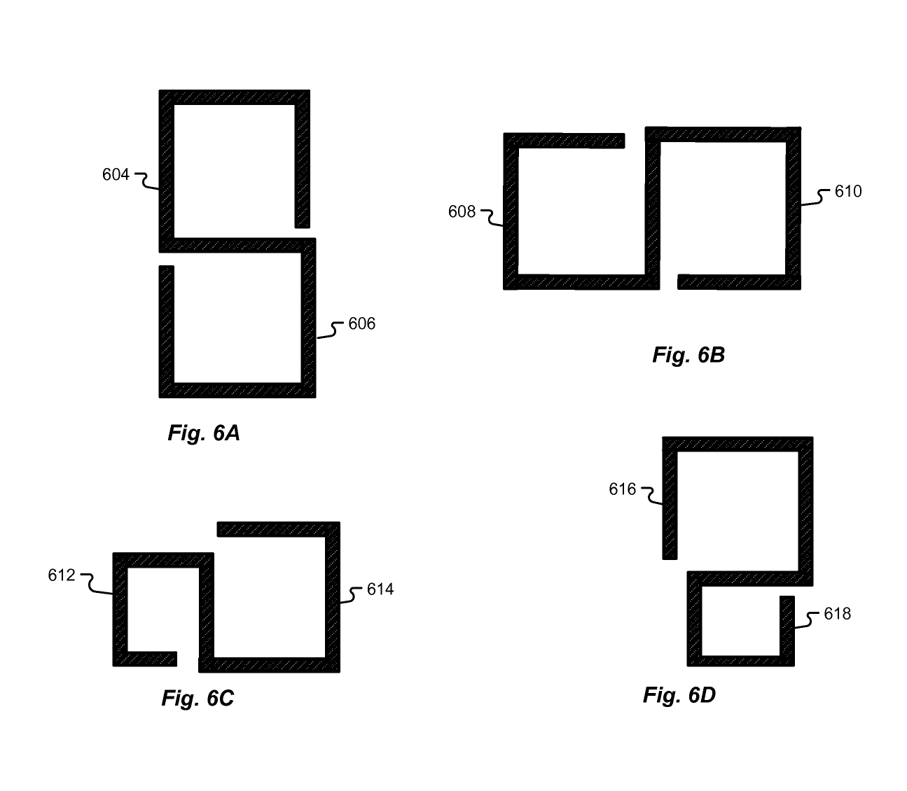

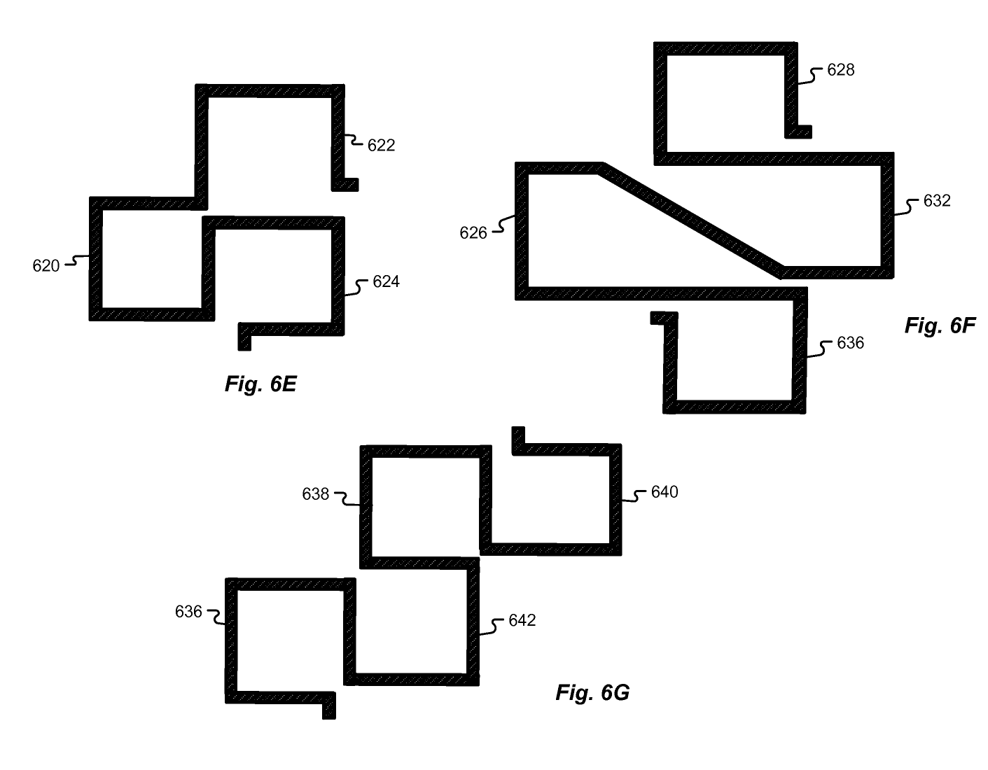

As described above, the figure eight directional coupler includes a main branch and a coupled branch which can lie in close proximity and are generally arranged in a figure eight. The arrangement of the branches can take on various configurations, some of which are illustrated in FIGS. 6A-6H. FIG. 6A-6D depict a general design where the branches lie next to each other (i.e., the top and bottom sub-coils lie in series and one of the branches lies underneath or beside each other) in a figure eight like configuration. The configuration of FIG. 6A begins by illustrating branches that have both vertical and horizontal symmetry. The figure is evenly distributed and the top sub-coils 604 lie above the bottom sub-coil 606. FIG. 6B depicts a figure eight coupler, where the configuration continues to have vertical and horizontal symmetry, and the sub-coils lie next to each other. The top sub-coils 608 can be situated on the left side, while the bottom sub-coils 610 is situated on the right. Alternatively, the top sub-coils 608 can be situated on the right side and the bottom sub-coils 610 on the left side.

FIG. 6C illustrates yet another figure eight configuration where the sub-coils 612, 614 lie next to each other. In FIG. 6C one or more of the sub-coils can be larger and/or smaller than the other sub-coil. This configuration can be used in instances, for example, where the magnetic noise arriving from the external components, reside or are dominant in one direction of the coupler. By allocating a larger sub-coil in the direction of the magnetic noise, the magnetic noise can be cancelled and the magnetic flux from the power amplifier, monitored circuit, other coupled component, or the like, of interest is detected with greater accuracy. As an example, the top sub-coil 612 in FIG. 6C is at least a proportion smaller than the bottom sub-coil 614. Alternatively, top sub-coil 612 is at least a portion larger than bottom sub-coil 614. In addition, top sub-coil 612 can lie to the right or to the left of bottom sub-coil 614 based in part on the direction of the magnetic noise.

Similar to FIG. 6C, FIG. 6D also depicts two sub-coils in series where at least one of the sub-coils is larger than the other. As an example, top sub-coil 616 can lie above bottom sub-coil 618 and top sub-coil 616 can be at least a portion larger than bottom sub-coil 618. As another example, top sub-coil 616 can lie above bottom sub-coil 618 and top sub-coil 616 can be at least a portion smaller than bottom sub-coil 618. As yet another example, top sub-coil 616 can lie below bottom sub-coil 618 and top sub-coil 616 can be at least a portion larger than bottom sub-coil 618. Still as another example, top sub-coil 616 can lie above bottom sub-coil 618 and top sub-coil 616 can be at least a portion larger than bottom sub-coil 618.

FIGS. 6E-6H provide other possible configurations wherein alternatives to the figure eight configuration are displayed for use as the directional coupler. FIG. 6E depicts a directional coupler with a shamrock-like configuration. In this configuration, two or more sub-coils can be connected for magnetic noise cancellation. The sub-coils can be strategically placed for greater magnetic noise cancellation and more accurate power detection. In FIG. 6E, for example, the top sub-coil 622 can be placed in the top, the bottom sub-coil 620 can be placed in the bottom left side with a middle sub-coil residing 624 on the bottom right of the coupler or just below the coupler. Alternatively, the top sub-coil 622 can be placed in any of the two bottom locations (i.e., left or right side) of the shamrock-like coupler. In addition, the bottom sub-coil 620 and middle sub-coil 624 can also be placed in any and all of the other locations within the shamrock-like coupler. Still further, the top and bottom sub-coils 620,624 can extend such that only two coils exist.

FIGS. 6F and 6G, like FIG. 6E provide alternate placement of the coils, configurations for the coupler, and/or combination thereof. FIG. 6F is clover-like coupler, with sub-coils 626, 628, 632, and 636 that can vary in location and size so as to provide the most accurate power reading. FIG. 6G, depicts at least two figure eight couples stacked for magnetic noise rejection. One or more of the coils can be at least a portion larger than the other and the branches can align or shift at least some distance from the other figure eight branch. FIG. 6G provides sub-coils 638, 640 placed in series and at least partially located above sub-coils 636, 642. Alternate placement of the coils are possible.

Location and placement of one or more sub-coils is not limited those depicted in FIGS. 6A-6H. Placement of sub-coils, coupler shape and number of sub-coils used are just some of the few variations that are possible in identifying the coupler that optimizes the power detected form the monitored circuit (i.e., power amplifier).

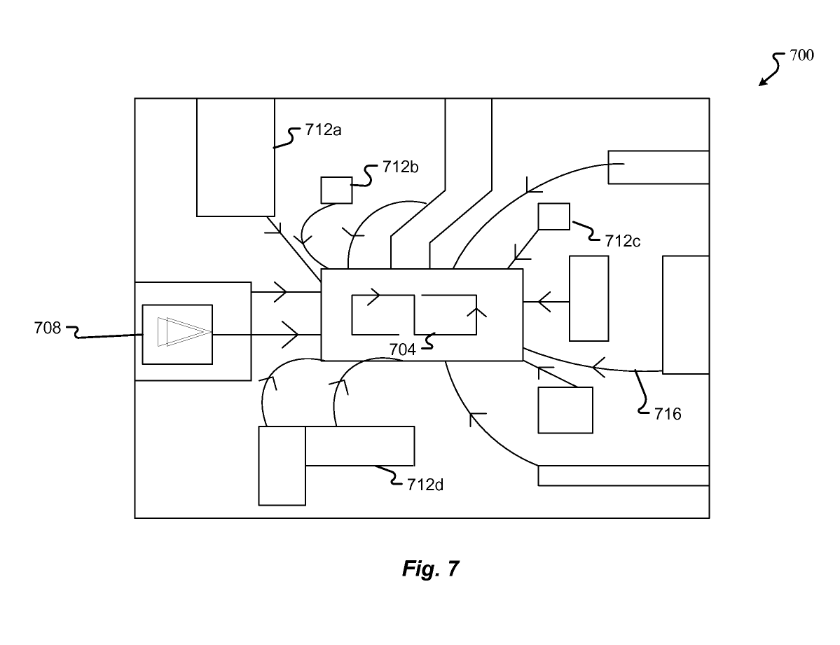

FIG. 7 depicts an integrated circuit chip 700 with at least a figure eight coupler 704 and a monitored circuit 708 in the presence of other components and/or circuits 712a-712d. The monitored circuit 708 can be a power amplifier and the other components and/or circuits 712a-712d can include inductors, transformers and other components whose signal is routed in proximity to at least one of the monitored circuit and figure eight coupler. The figure eight coupler 704 as described above and in conjunction with FIGS. 2-6 can include at least a main branch and coupled branch. The main branch coil can be configured to receive current from the monitored circuit 708 and convert the received current into a magnetic field. The coupled branch can be configured to receive the magnetic field created by the main branch. The magnetic field induces a current on the coupled branch in response to the received magnetic field by the main branch. The induced current flowing in the coupled branch is indicative of the current received at the main branch from the monitored circuit 708. The figure eight coupler 704 is configured (main branch and the couple branch placement), such that the magnetic noise 716 (i.e., electromagnetic interference) from the external components and/or circuits 712a-712d is rejected.

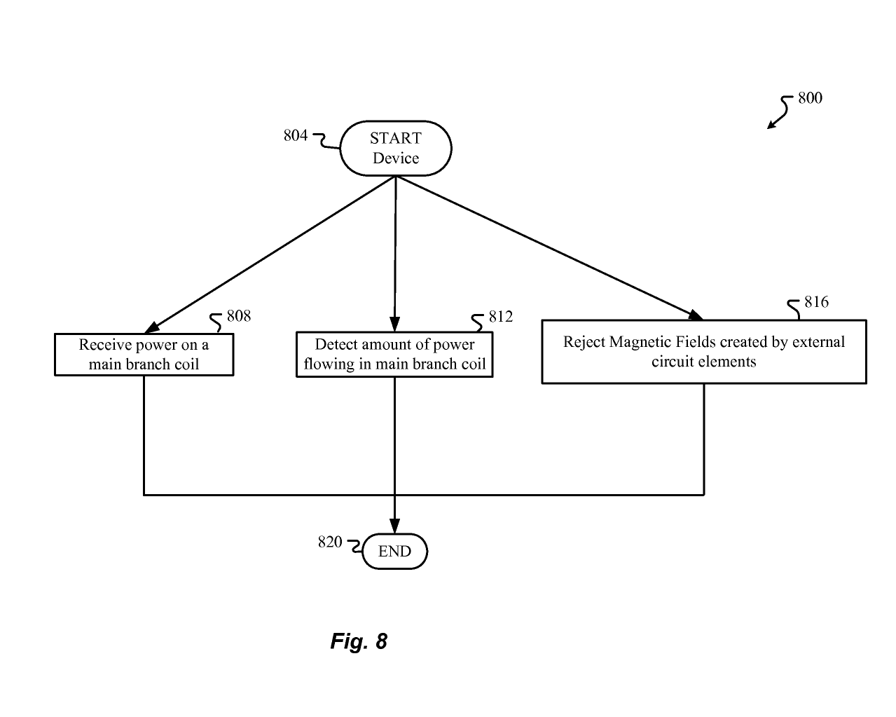

FIG. 8 outlines an exemplary flowchart illustrating external noise rejection. In particular, external noise rejection by a directional coupler begins at step 804 and continues to step 808. In step 808 a directional coupler which can reside on an integrated circuit chip with a figure eight configuration, receives a current on a main branch coil. The directional coupler can also contain at least a coupled branch coil and be situated in proximity to a monitored circuit (i.e., power amplifier), inductors, transformers and other components on the integrated circuit chip. The directional coupler can also have a figure eight configuration with varying top and bottom sub-soil size, shapes, placement, quantity, etc., as depicted and described above and in conjunction with FIGS. 6A-6G.

The current received by the main branch coil of the directional coupler in step 808 is detected by the coupled branch coil in step 812. The detection by the coupled branch can occur concurrently as the current is received by the main branch or following detection. In addition to the current induced by the main branch coil, the coupled branch coil can also detect magnetic noise created by external components. This external noise is rejected in step 816. The external noise is rejected as the net electromagnetic force across the entire coupled branch coil is zero. The external noise that is rejected can occur also occur concurrently with the current received by the main branch and as the amount of power flowing in the main branch is detected.

As previously described, the coupled branch can include two sub-coils in series with opposite polarity. The two sub-coils in the coupled branch coil can be connected in series. External components and circuits in proximity to the directional coupler can induce magnetic noise that may have opposite polarities from the two sub-coils in the couple branch coil. The opposing polarities from the two sub-coils and the magnetic fields from the external components produces a net electromagnetic force across the entire coupled branch coil equal to zero. As a result, a more accurate measurement of the current received from the main branch coil is achieved and the process ends at step 820.

Specific details were given in the description to provide a thorough understanding of the embodiments. However, it will be understood by one of ordinary skill in the art that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A coupler, comprising:
a main branch coil configured to receive current from a monitored circuit and carry the current through the main branch coil;
a coupled branch coil positioned in proximity to the main branch coil and configured to detect an amount of current flowing in the main branch coil via an inductive coupling between the coupled branch coil and the main branch coil, wherein at least one of the main branch coil and coupled branch coil are configured to at least partially reject external magnetic fields that are created by circuit elements other than the main branch coil.

2. The coupler of claim 1, wherein the main branch coil comprises a first sub-coil and a second sub-coil that are interconnected to one another, wherein the first sub-coil creates a magnetic field in a direction that at least partially opposes a magnetic field created by the second sub-coil.

3. The coupler of claim 2, wherein the first sub-coil comprises a polarity that opposes a polarity of the second sub-coil.

4. The coupler of claim 3, wherein the first sub-coil and second sub-coil are interconnected to one another to make a figure-eight configuration.

5. The coupler of claim 4, wherein the coupled branch coil also forms a figure-eight configuration that substantially coincides with the figure-eight configuration of the main branch coil.

6. The coupler of claim 4, wherein the first sub-coil and second sub-coil are substantially the same size.

7. The coupler of claim 4, wherein the first sub-coil and second sub-coil are different sizes and a larger of the first sub-coil and second sub-coil are positioned closer to the circuit elements other than the main branch coil that contribute more external magnetic field to the main branch coil.

8. The coupler of claim 1, wherein the coupled branch coil has current induced therein by a magnetic field created by the current flowing in the main branch coil and wherein the current flowing in the coupled branch coil is used to create a power measurement for the monitored circuit.

9. The coupler of claim 8, wherein the monitored circuit comprises a power amplifier.

10. A coupling system, comprising:
a first coil configured to carry a first current and create at least a first magnetic field in response to the first current flowing therethrough;
a second coil configured to carry a second current that is created in response to the first magnetic field passing through the second coil, wherein the first coil and second coil are positioned proximate to one another, and wherein at least one of the first coil and second coil are configured to create a net electromotive force of approximately zero.

11. The system of claim 10, wherein the first coil comprises a first sub-coil and a second sub-coil connected in series with one another, wherein the first sub-coil creates an electromotive force that opposes an electromotive force created in the second sub-coil thereby creating the net electromotive force of approximately zero.

12. The system of claim 11, wherein the second coil also comprises a first sub-coil and a second sub-coil that are connected in series with one another.

13. The system of claim 12, wherein the first sub-coil of the first coil and the first sub-coil of the second coil are substantially the same size and are substantially coincident with one another.

14. The system of claim 11, wherein the first sub-coil and second sub-coil create a figure-eight configuration.

15. The system of claim 11, wherein the first coil further comprises a third sub-coil that is connected in series with at least one of the first sub-coil and second sub-coil.

16. The system of claim 10, wherein the first coil and second coil are both established on a common silicon chip.

17. An electronic device, comprising:
an Integrated Circuit (IC) chip, comprising:
a monitored circuit;
a source of electromagnetic interference;
a main branch coil configured to receive current from the monitored circuit and convert the received current into a magnetic field; and
a coupled branch coil configured to receive the magnetic field created by the main branch coil and in response to receiving the magnetic field create an induced current therein, wherein the induced current flowing in the coupled branch coil is indicative of the current received at the main branch coil from the monitored circuit, and wherein at least one of the main branch coil and coupled branch coil are configured to reject the electromagnetic interference created by the source of electromagnetic interference.

18. The communication device of claim 17, wherein the main branch coil comprises a figure-eight configuration.

19. The communication device of claim 18, wherein the coupled branch coil comprises a figure-eight configuration that substantially matches the figure-eight configuration of the main branch coil.

20. The communication device of claim 18, wherein a first loop of the figure-eight configuration and a second loop of the figure-eight configuration are configured to cancel effects of the electromagnetic interference created by the electromagnetic interference.
